(19) United States
(12) Patent Application Publication
(10) Pub. No.: US 2025/0031558 A1
(43) Pub. Date: Jan. 23, 2025

(54) MULTI-SIDED LIGHT-EMITTING DISPLAY APPARATUS

(71) Applicant: Samsung Display Co., Ltd., Yongin-Si (KR)

(72) Inventors: Ohjune Kwon, Yongin-si (KR); Heejun Yang, Yongin-si (KR); Jeongseok Lee, Yongin-si (KR); Seungyeon Chae, Yongin-si (KR)

(21) Appl. No.: 18/607,551

(22) Filed: Mar. 18, 2024

(30) Foreign Application Priority Data
Jul. 20, 2023 (KR) 10-2023-0094656

(51) Int. Cl. H10K 59/95; H10K 59/00

(52) U.S. Cl. CPC H10K 59/95; H10K 59/751

(57) ABSTRACT

A multi-sided light-emitting display apparatus includes a first display panel including a first display area, and a 1-1 edge area and a 1-2 edge area on opposite sides of the first display area, and a second display panel including a second display area, and a 2-1 edge area and a 2-2 edge area on opposite sides of the second display area. The second display panel is assembled with the first display panel with the 1-1 edge area and the 1-2 edge area being bent toward the second display area, and the 2-1 edge area and the 2-2 edge area being bent toward the first display area.

### CROSS-REFERENCE TO RELATED APPLICATION

This application is based on and claims priority under 35 U.S.C. § 119 to Korean Patent Application No. 10-2023-0094656, filed on Jul. 20, 2023, in the Korean Intellectual Property Office, the disclosure of which is incorporated by reference herein in its entirety.

### BACKGROUND

### 1. Field

One or more embodiments relate to a multi-sided light-emitting display apparatus, and more particularly, to a multi-sided light-emitting display apparatus that may be simply assembled using only a first display panel and a second display panel.

### 2. Description of the Related Art

A display apparatus is an apparatus that receives information about an image and displays the image. A display apparatus may be used as a display for a small product such as a mobile phone or as a display for a large product such as a television. A display apparatus typically includes pixels that receive electrical signals and emit light to display an image. Each pixel may include a light-emitting device. For example, organic light-emitting display apparatuses include organic light-emitting diodes (OLEDs) as light-emitting devices. In general, in an organic light-emitting display apparatus, a thin-film transistor and an OLED of a pixel are formed on a substrate, and the OLED emits light. Recently, the demand for multi-sided light-emitting display apparatuses with a multi-sided screen for displaying an image in multiple directions rather than in only one direction has increased.

### SUMMARY

One or more embodiments include a multi-sided light-emitting display apparatus that may be simply assembled using only a first display panel and a second display panel.

According to one or more embodiments, a multi-sided light emitting display apparatus includes a first display panel comprising a first display area, and a 1-1 edge area and a 1-2 edge area located on opposite sides of the first display area, and a second display panel comprising a second display area facing the first display area, and a 2-1 edge area and a 2-2 edge area located on opposite sides of the second display area, the second display panel being assembled with the first display panel, wherein the 1-1 edge area and the 1-2 edge area are bent toward the second display area, and the 2-1 edge area and the 2-2 edge area are bent toward the first display area.

The 1-1 edge area and the 1-2 edge area may face each other, and the 2-1 edge area and the 2-2 edge area may face each other.

The edge areas may constitute a side display area of the multi-sided light-emitting display apparatus, and the first display area and the second display area may constitute a front display area and a rear display area of the multi-sided light-emitting display apparatus.

A distance between the 1-1 edge area and the 1-2 edge area in a bent state may be equal to a short width of the second display area.

The distance between the 1-1 edge area and the 1-2 edge area in the bent state may be equal to a long width of the 2-1 edge area.

The distance between the 1-1 edge area and the 1-2 edge area in the bent state may be equal to a long width of the 2-2 edge area.

A long width of the 1-1 edge area may be equal to a long width of the first display area.

A long width of the 2-1 edge area may be equal to a short width of the second display area.

The first display area, the 1-1 edge area, and the 1-2 edge area in a bent state may cover side surfaces of the 2-1 edge area.

The 1-1 edge area and the 1-2 edge area in the bent state may cover both side surfaces of the second display area.

The first display area, the 1-1 edge area, and the 1-2 edge area in the bent state may cover side surfaces of the 2-2 edge area.

The multi-sided light-emitting display apparatus may further include a first driving circuit unit for driving the first display panel, and a second driving circuit unit for driving the second display panel.

At least one of the first driving circuit unit and the second driving circuit unit may be located in an inner space of the first display panel and the second display panel in an assembled state.

The 2-1 edge area may include a first through-hole for connecting an inner space and an outer space of the first display panel and the second display in an assembled state.

The second driving unit may be connected to an end of the 2-2 edge area.

The second display area may include a second through-hole for connecting an inner space and an outer space of the first display panel and the second display panel in an assembled state.

The multi-sided light-emitting display apparatus may further include a camera device in the inner space corresponding to the second through-hole.

The second driving unit may be connected to one side surface of the second display area.

The second through-hole may be located closer to the 2-1 edge area than the 2-2 edge area.

The second driving unit may be located closer to the 2-2 edge area than the 2-1 edge area.

### BRIEF DESCRIPTION OF THE DRAWINGS

The above and other aspects, features, and advantages of certain embodiments will be more apparent from the following description taken in conjunction with the accompanying drawings.

FIG. 1 schematically illustrates a first display panel of a multi-sided light-emitting display apparatus according to an embodiment.

FIG. 2 schematically illustrates a second display panel of the multi-sided light-emitting display apparatus according to an embodiment.

FIG. 3 is a schematic cross-sectional view taken along line A-A′ of the first display panel of FIG. 1.

FIG. 4 is a schematic cross-sectional view taken along line B-B′ of the second display panel of FIG. 2.

FIG. 5 is an equivalent circuit diagram illustrating one pixel included in the first display panel of FIG. 1 or the second display panel of FIG. 2.

FIG. 6 is a cross-sectional view schematically illustrating a part of the first display panel of FIG. 1 or the second display panel of FIG. 2.

FIGS. 7 and 8 are perspective views illustrating a multi-sided light-emitting display apparatus including the first display panel of FIG. 1 and the second display panel of FIG. 2, according to an embodiment.

FIG. 9 schematically illustrates a first example where a first driving circuit is attached to the first display panel of FIG. 1.

FIG. 10 schematically illustrates a second example where a first driving circuit is attached to the first display panel of FIG. 1.

FIG. 11 schematically illustrates a third example where a second driving circuit is attached to the second display panel of FIG. 2.

FIG. 12 schematically illustrates a fourth example where a second driving circuit is attached to the second display panel of FIG. 2,

FIG. 13 is a perspective view schematically illustrating the second display panel including a second through-hole.

FIG. 14 schematically illustrates a fifth example where a second driving circuit is attached to the second display panel of FIG. 13.

FIG. 15 schematically illustrates a sixth example where a second driving circuit is attached to the second display panel of FIG. 13.

FIG. 16 is a schematic perspective view illustrating the second display panel including a first through-hole and a second through-hole.

FIG. 17 schematically illustrates a seventh example where a second driving circuit is attached to the second display panel of FIG. 16.

FIG. 18 schematically illustrates an eighth example where a second driving circuit is attached to the second display panel of FIG. 16.

FIG. 19 is a perspective view schematically illustrating an embodiment of the multi-sided light-emitting display apparatus in which the first display panel of FIG. 1 and the display panel of FIG. 16 are assembled.

FIG. 20 is a perspective view schematically illustrating a multi-sided light-emitting display apparatus, according to another embodiment.

FIG. 21 schematically illustrates a display apparatus, according to a comparative example.

### DETAILED DESCRIPTION

Reference will now be made in detail to embodiments, examples of which are illustrated in the accompanying drawings. In this regard, the present embodiments may have different forms and should not be construed as being limited to the descriptions set forth herein. Accordingly, the embodiments are merely described below, by referring to the figures, to explain aspects of the present description.

As the disclosure allows for various changes and numerous embodiments, only certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof may be omitted. Also, sizes of components in the drawings may be exaggerated or reduced for convenience of explanation. For example, because sizes and thicknesses of elements in the drawings may be arbitrarily illustrated for convenience of explanation, the disclosure is not limited thereto.

As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

It will be understood that when a component, such as a layer, a film, a region, or a plate, is referred to as being “on” another component, the component may be directly on the other component or intervening components may be present therebetween.

In the following embodiments, the x-axis, the y-axis and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

A multi-sided light-emitting display apparatus according to an embodiment will be described in detail based on the above understandings.

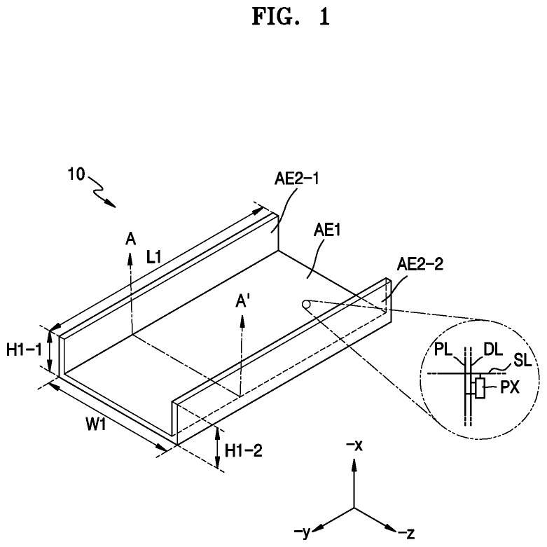

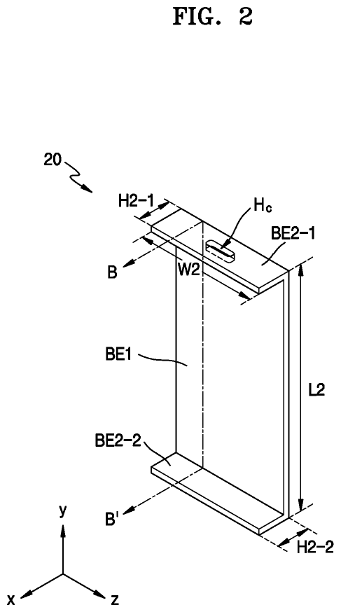

FIG. 1 is a view schematically illustrating a first display panel of a multi-sided light-emitting display apparatus, according to an embodiment. FIG. 2 is a view schematically illustrating a second display panel of the multi-sided light-emitting display apparatus according to an embodiment.

A multi-sided light-emitting display apparatus according to an embodiment may include a first display panel 10 as shown in FIG. 1 and a second display panel 20 as shown in FIG. 2. The multi-sided light-emitting display apparatus may be used in various devices such as a smartphone, a tablet, a laptop, a television, and a billboard.

The first display panel 10 may include a first display area AE1, a 1-1 edge area AE2-1, and a 1-2 edge area AE2-2. In FIG. 1, the first display panel 10, particularly the display area AE1, has a rectangular shape. However, the disclosure is not limited thereto. The first display panel 10 may have any of various shapes such as a circular shape, an elliptical shape, a polygonal shape, or any specific geometric shape.

A plurality of pixels PX may be located in the first display panel 10 where an image is displayed. The plurality of pixels PX may be located in at least one of the first display area AE1, the 1-1 edge area AE2-1, and the 1-2 edge area AE2-2, and particularly may be in all of the first display area AE1, the 1-1 edge area AE2-1, and the 1-2 edge area AE2-2.

A pixel PX located in the first display area AE1, for example, may mainly emit light in an x axis direction, a pixel PX located in the 1-1 edge area AE2-1 may mainly emit light in a z axis direction, and the pixel PX located in the 1-2 edge area AE2-2 may mainly emit light in a −z axis direction. However, the pixels PX located in the 1-1 edge area AE2-1 and the 1-2 edge area AE2-2 may emit light in different directions according to a degree to or angle at which the 1-1 edge area AE2-1 and the 1-2 edge area AE2-2 are bent (or folded).

Each pixel PX may include a light-emitting device such as an organic light-emitting diode. Each pixel PX may emit, for example, red light, green light, or blue light. The light emitting device in each pixel PX may be connected to a pixel circuit including a thin-film transistor (TFT) and a storage capacitor. Each pixel circuit may be connected to a scan line SL through which a scan signal is transmitted, a data line DL that intersects the scan line SL and through which a data signal is transmitted, and a driving voltage line PL through which a driving voltage is supplied. The scan lines SL may extend in one direction, and the data lines DL and the driving voltage lines PL may extend in another direction intersecting the one direction.

Each pixel PX may emit light having a luminance corresponding to an electrical signal from the pixel circuit that is electrically connected to the pixel PX. A display area DA may display a certain image through light emitted from the pixels PX. For reference, as described above, each pixel PX may be defined as an emission area that emits light of any one of red, green, and blue colors.

Although not shown in FIGS. 1 and 2, each of the first display panel 10 and the second display panel 20 may include a display area and a peripheral area. The display area may be an area where the pixels PX are located, and the peripheral area may be an area where the pixels PX are not located and an image is not displayed. In the peripheral area, power supply wiring for driving the pixels PX may be located. Also, in the peripheral area, a plurality of pads may be located, and an integrated circuit device such as a driver IC or a printed circuit board including a driving circuit unit may be electrically connected to the pads.

A plurality of transistors may be located in the first display panel 10 and the second display panel 20. In each of the transistors, a first terminal of the transistor may be a source electrode or a drain electrode, and a second terminal may be an electrode different from the first terminal, according to a type (N-type or P-type) and/or an operating condition of the transistor. For example, when the first terminal is a source electrode, the second terminal may be a drain electrode.

The plurality of transistors may include a driving transistor, a data write transistor, a compensation transistor, an initialization transistor, and an emission control transistor, which may be components of a pixel circuit for a pixel PX. The driving transistor may be connected between the driving voltage line PL and an organic light-emitting diode OLED. The data write transistor may be connected to the data line DL, and the driving transistor and may perform a switching operation of transmitting a data signal transmitted through the data line DL.

The compensation transistor may be turned on according to a scan signal received through the scan line SL to connect the driving transistor to the organic light-emitting diode OLED and compensate for a threshold voltage of the driving transistor.

The initialization transistor may be turned on according to a scan signal received through the scan line SL to transmit an initialization voltage to a gate electrode of the driving transistor and initialize the gate electrode of the driving transistor. The scan line connected to the initialization transistor may be a separate scan line different from the scan line connected to the compensation transistor.

The emission control transistor may be turned on according to an emission control signal received through an emission control line so that driving current flows through the organic light-emitting diode OLED.

The organic light-emitting diode OLED may include a pixel electrode (anode) and a counter electrode (cathode), and the counter electrode 170 may receive a second power supply voltage ELVSS. The organic light-emitting diode OLED may receive the driving current from the driving transistor to emit light and display an image.

Hereinafter, although an organic light-emitting display apparatus is described as a display apparatus according to an embodiment, the display apparatus of the disclosure is not limited thereto. In another embodiment, the display apparatus may be an inorganic light-emitting display apparatus or an inorganic electroluminescent (EL) display apparatus, or a quantum dot light-emitting display apparatus. For example, an emission layer of a light emitting device included in the display apparatus may include an organic material or an inorganic material. Also, the light emitting device may include an emission layer and quantum dots located in a path of light emitted from the emission layer.

As shown in FIG. 1, the first display panel 10 may include the first display area AE1, the 1-1 edge area AE2-1, and the 1-2 edge area AE2-2. The 1-1 edge area AE2-1 and the 1-2 edge area AE2-2 may be located on opposite sides of the first display area AE1 and may extend from opposite edges of the first display area AE1. The first display area AE1 may have a long width L1 and a short width W1. The long width L1 may have a length greater than that of the short width W1.

In an unfolded state, the 1-1 edge area AE2-1 may extend outward from one long side or edge of the first display area AE1. The 1-1 edge area AE2-1 may be a bendable or foldable component and may be bent or folded from one long side of the first display area AE1, e.g., to extend in a −x axis direction. The 1-1 edge area AE2-1 may include a long side having a length corresponding to the long width L1 of the first display area AE1 and a short side having a length H1-1 less than that of the short width W1 of the first display area AE1.

In an unfolded state, the 1-2 edge area AE2-2 may extend outward from the other long side or edge of the first display area AE1. The 1-2 edge area AE2-2 may be a bendable or foldable component and may be bent or folded from one long side of the first display area AE1, e.g., to extend in the −x axis direction. The 1-2 edge area AE2-2 may include a long side having a length corresponding to the long width L1 of the first display area AE1 and a short side having a length H1-2 less than that of the short width W1 of the first display area AE1.

In a bent state, the 1-1 edge area AE2-1 and the 1-2 edge area AE2-2 may be parallel to each other. That is, the 1-1 edge area AE2-1 and the 1-2 edge area AE2-2 may face each other.

As shown in FIG. 2, the second display panel 20 may include a second display area BE1, a 2-1 edge area BE2-1, and a 2-2 edge area BE2-2. The 2-1 edge area BE2-1 and the 2-2 edge area BE2-2 may be located on opposite sides of the second display area BE1. The second display area BE1 may have a long width L2 and a short width W2. The long width L2 may have a length greater than that of the short width W2.

In an unfolded state, the 2-1 edge area BE2-1 may extend outward from one short side of the second display area BE1. The 2-1 edge area BE2-1 may be a bendable or foldable component and may be bent or folded from one short side of the second display area BE1, e.g., to extend in a +x axis direction. The 2-1 edge area BE2-1 may include a long side having a length corresponding to the short width W2 of the second display area BE1 and a short side having a length H2-1 less than that of the short width W2 of the first display area AE1.

In an unfolded state, the 2-2 edge area BE2-2 may extend outward from the other short side of the second display area BE1. The 2-2 edge area BE2-2 may be a bendable or foldable component and may be bent or folded from one long side of the second display area BE1, e.g., to extend in the +x axis direction. The 2-2 edge area BE2-2 may include a long side having a length corresponding to the short width W2 of the second display area BE1 and a short side having a length H2-2 less than that of the short width W2 of the second display area BE1.

In a bent state, the 2-1 edge area BE2-1 and the 2-2 edge area BE2-2 may be parallel to each other. That is, the 2-1 edge area BE2-1 and the 2-2 edge area BE2-2 may face each other.

The first display panel 10 and the second display panel 20 may fit together to form multi-sided light-emitting display apparatus. For example, a virtual line connecting the center of the 1-1 edge area AE2-1 to the center of the 1-2 edge area AE2-2 in the bent state may intersect or perpendicularly intersect a virtual line connecting the center of the 2-1 edge area BE2-1 to the center of the 2-2 edge area BE2-2 in the bent state.

As shown in FIG. 2, a first through-hole Hc may be located in the 2-1 edge area BE2-1. That is, the 2-1 edge area BE2-1 may include the first through-hole Hc. The first through-hole Hc may be a through-hole for connecting inside and outside components of the multi-sided light-emitting display apparatus in an assembled state. For example, a wiring for transmitting power or an electrical signal required for a driving circuit inside the multi-sided light-emitting display apparatus in the assembled state may connect the driving circuit to the outside of the multi-sided light-emitting display apparatus through the first through-hole Hc.

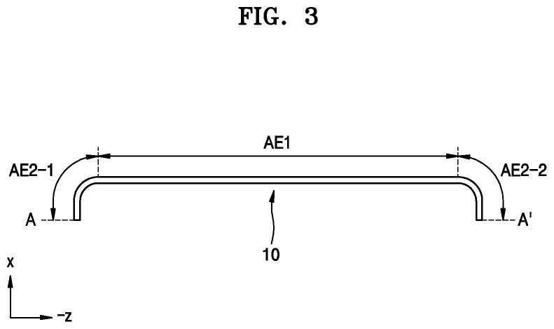

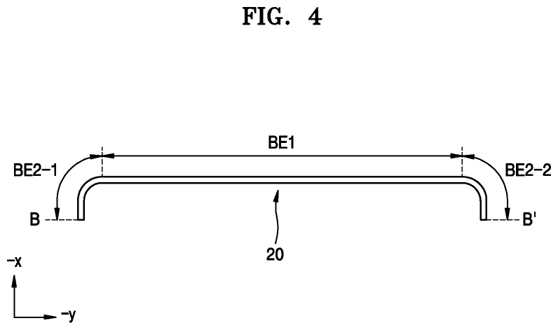

FIG. 3 is a schematic cross-sectional view taken along line A-A′ of the first display panel 10 of FIG. 1. FIG. 4 is a schematic cross-sectional view taken along line B-B′ of the second display panel 20 of FIG. 2. For reference, in the description of FIGS. 3 and 4, descriptions of structure for one display panel 10 or 20 that is similar to or the same as corresponding structure for the other display panel 20 or 10 apply to both display panels 10 and 20 and may not be repeated below.

As shown in FIG. 3, the 1-1 edge area AE2-1 may be bent relative to the first display area AE1 and may particularly be bent or folded toward the −x axis direction. That is, an end portion of the 1-1 edge area AE2-1 may extend toward the −x axis direction, and a portion where the 1-1 edge area AE2-1 and the first display area AE1 are connected to each other may be flexible.

As shown in FIG. 3, the 1-2 edge area AE2-2 may be bent relative to the first display area AE1 and may particularly be bent or folded toward the −x axis direction. That is, an end portion of the 1-2 edge area AE2-2 may extend toward the −x axis direction, and a portion where the 1-2 edge area AE2-2 and the first display area AE1 are connected to each other may be flexible.

As shown in FIG. 4, the 2-1 edge area BE2-1 may be bent from the second display area BE1 and bent or folded toward the x axis direction. That is, an end of the 2-1 edge area BE2-1 may extend toward the x axis direction, and a portion where the 2-1 edge area BE2-1 and the second display area BE1 are connected to each other may have a flexible structure.

As shown in FIG. 4, the 2-2 edge area BE2-2 may be bent relative to the second display area BE1 and may particularly be bent or folded toward the x axis direction. That is, an end portion of the 2-2 edge area BE2-2 may extend toward the x axis direction, and a portion where the 2-2 edge area BE2-2 and the second display area BE1 are connected to each other may be flexible.

Also, although not shown in FIGS. 3 and 4, a driving chip (not shown) may be located on a rear surface (i.e., a surface on which an image is not displayed) of each of the first display panel 10 and the second display panel 20. The driving chips (not shown) may include integrated circuits for driving the first display panel 10 and the second display panel 20. The integrated circuits may be, but are not limited to, a data driving integrated circuit for generating a data signal.

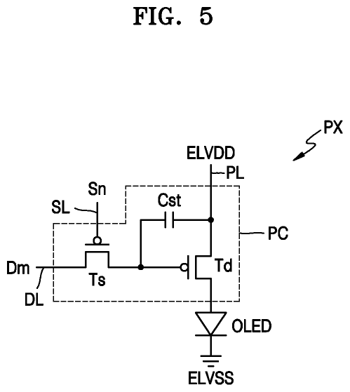

FIG. 5 is an equivalent circuit diagram illustrating one pixel PX that may be included in the first display panel 10 of FIG. 1 or the second display panel 20 of FIG. 2. For reference, in the description of FIG. 5, description that was already provided above with reference to FIGS. 1 to 4 may not be duplicated below.

As shown in FIG. 5, each pixel PX includes a pixel circuit PC connected to the driving voltage line PL, the scan line SL, the data line DL, and an organic light-emitting diode OLED, which are associated with the pixel PX.

The pixel circuit PC includes a driving thin-film transistor Td, a switching thin-film transistor Ts, and a storage capacitor Cst. The switching thin-film transistor Ts is connected to the scan line SL and the data line DL, and transmits a data signal Dm input through the data line DL to the driving thin-film transistor Td according to a scan signal Sn input through the scan line SL.

The storage capacitor Cst is connected to the switching thin-film transistor Ts and the driving voltage line PL, and stores a voltage corresponding to a difference between a voltage received from the switching thin-film transistor Ts and a first power supply voltage ELVDD supplied to the driving voltage line PL.

A second power supply voltage ELVSS may be a driving voltage having a lower level than the first power supply voltage ELVDD. A level of a driving voltage supplied to each pixel PX may be a difference between levels of the first power supply voltage ELVDD and the second power supply voltage ELVSS.

The driving thin-film transistor Td may be connected to the driving voltage line PL and the storage capacitor Cst, and a value of the voltage stored in the storage capacitor Cst and applied to the gate of the driving thin-film transistor Td may control the driving current flowing from the driving voltage line PL to the organic light-emitting diode OLED. The organic light-emitting diode OLED may emit light having a luminance corresponding to the driving current.

Although the pixel circuit PC includes two thin-film transistors and one storage capacitor in FIG. 5, the disclosure is not limited thereto. The pixel circuit PC may include two or more storage capacitors and one or more additional thin-film transistors (not shown).

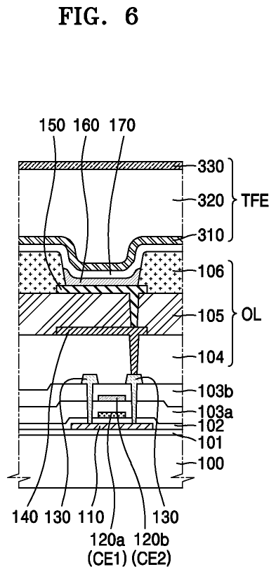

FIG. 6 is a cross-sectional view schematically illustrating a part of the first display panel 10 of FIG. 1 or the second display panel 20 of FIG. 2. For reference, in the description of FIG. 6, description that was already provided above with reference to FIGS. 1 to 5 may not be duplicated below.

FIG. 6 shows structures that may be fabricated on a substrate 100. The substrate 100 may include any of various flexible or bendable materials. For example, the substrate 100 may include glass, a metal, or a polymer resin of a suitable thickness to permit desired bending. In one example, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. However, various modifications may be made. For example, the substrate 100 may have a multi-layer structure including two layers each including a polymer resin and a barrier layer including an inorganic material (e.g., silicon oxide, silicon nitride, or silicon oxynitride) and located between the two layers.

A buffer layer 101 may be located on the substrate 100. The buffer layer 101 may function as a barrier layer and/or a blocking layer for preventing diffusion of impurity ions, preventing penetration of moisture or external air, and planarizing a surface. The buffer layer 101 may include silicon oxide, silicon nitride, or silicon oxynitride. Also, the buffer layer 101 may adjust a heat supply speed during a crystallization process for forming a semiconductor layer 110 so that the semiconductor layer 110 is uniformly crystalized.

The semiconductor layer 110 may be located on the buffer layer 101. The semiconductor layer 110 may be formed of polysilicon and may include a channel region not doped with impurities and a source region and a drain region formed by doping impurities on opposite sides of the channel region. The impurities may vary according to a type of a thin film transistor and may be N-type impurities or P-type impurities.

A gate insulating film 102 may be located on the semiconductor layer 110. The gate insulating film 102 may be an element for ensuring insulation between the semiconductor layer 110 and a gate layer 120. The gate insulating film 102 may include an inorganic material such as silicon oxide, silicon nitride, and/or silicon oxynitride, and may be located between the semiconductor layer 110 and the gate layer 120. Also, the gate insulating film 102 may be formed to correspond to an entire surface of the substrate 100, and contact holes may be formed through the gate insulating film 102 at desired locations. As such, an insulating film including an inorganic material may be formed by using chemical vapor deposition (CVD) or atomic layer deposition (ALD). This applies to the following embodiments and modifications thereof.

A first gate layer 120a may be located on the gate insulating film 102. The first gate layer 120a may vertically overlap the semiconductor layer 110, and may include at least one metal from among molybdenum (Mo), aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (W).

A first interlayer insulating film 103a may be located on the first gate layer 120a. The first interlayer insulating film 103a may cover the first gate layer 120a. The first interlayer insulating film 103a may be formed of an inorganic material. For example, the first interlayer insulating film 103a may be formed of a metal oxide or a metal nitride. In detail, the inorganic material may include silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZrO₂). The first interlayer insulating film 103a may have a multi-layer structure formed of SiOₓ/SiN_{y} or SiNₓ/SiO_{y} in some embodiments.

A second gate layer 120b may be located on the first interlayer insulating film 103a. The second gate layer 120b may vertically overlap the first gate layer 120a, and may include at least one metal from among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (W).

The second gate layer 120b and the first gate layer 120a may constitute the storage capacitor Cst described with reference to FIG. 2. The first gate layer 120a may include a first electrode portion of the storage capacitor Cst, and the second gate layer 120b may include a second electrode portion of the storage capacitor Cst.

When viewed in a direction perpendicular to the substrate 100, the area of the second gate layer 120b may be greater than the area of the first gate layer 120a. When viewed in a direction perpendicular to the substrate 100, the second gate layer 120b may cover the first gate layer 120a.

A second interlayer insulating film 103b may be located on the second gate layer 120b. The second interlayer insulating film 103b may cover the second gate layer 120b. The second interlayer insulating film 103b may be formed of an inorganic material. For example, the second interlayer insulating film 103b may be formed of a metal oxide or a metal nitride. In detail, the inorganic material may include silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZrO₂). The second interlayer insulating film 103b may have a multi-layer structure formed of SiOₓ/SiN_{y} or SiNₓ/SiO_{y} in some embodiments.

A first conductive layer 130 may be located on the second interlayer insulating film 103b. The first conductive layer 130 may include a region that functions as an electrode connected to the source/drain region of the semiconductor layer through a through-hole formed in the second interlayer insulating film 103b, the first interlayer insulating film 103a, and the gate insulating film 102. The first conductive layer 130 may include at least one metal selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the first conductive layer 130 may include a Ti layer, an Al layer, and/or a Cu layer.

A first organic insulating layer 104 may be located on the first conductive layer 130. The first organic insulating layer 104 may cover an upper portion of the first conductive layer 130 and may have a substantially flat top surface, and thus, may be an organic insulating layer functioning as a planarization film. The first organic insulating layer 104 may include, for example, an organic material such as acryl, benzocyclobutene (BCB), or hexamethyldisiloxane (HMDSO). Various modifications may be made. For example, the first organic insulating layer 104 may have a single-layer or multi-layer structure.

A second conductive layer 140 may be located on the first organic insulating layer 104. The second conductive layer 140 may function as an electrode connected to the source/drain region of the semiconductor layer 110 through a through-hole formed in the first organic insulating layer 104 to the first conductive layer 130. The second conductive layer 140 may include at least one metal selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the second conductive layer 140 may include a Ti layer, an Al layer, and/or a Cu layer.

A second organic insulating layer 105 may be located on the second conductive layer 140. The second organic insulating layer 105 may cover an upper portion of the second conductive layer 140 and may have a substantially flat top surface, and thus, may be an organic insulating layer functioning as a planarization film. The second organic insulating layer 105 may include, for example, an organic material such as acryl, benzocyclobutene (BCB), or hexamethyldisiloxane (HMDSO). Various modifications may be made. For example, the second organic insulating layer 105 may have a single-layer or multi-layer structure.

Also, although not shown in FIG. 6, an additional conductive layer and an additional insulating layer may be located between the conductive layer 140 and a pixel electrode and may be applied in various embodiments. In this case, the additional conductive layer and the conductive layer 140 may include the same material and may have the same layer structure. The additional insulating layer and the organic insulating layer 105 may include the same material and have the same layer structure.

A pixel electrode 150 may be located on the second organic insulating layer 105. The pixel electrode 150 may be connected to the second conductive layer 140 through a contact hole formed in the second organic insulating layer 105. A light-emitting device may be located on the pixel electrode 150. An organic light-emitting diode OLED may be used as the light-emitting device. That is, the organic light-emitting diode OLED may be located on, for example, the pixel electrode 150. The pixel electrode 150 may include a light-transmitting conductive layer formed of a light-transmitting conductive oxide such as ITO, In₂O₃, or IZO, and a reflective layer formed of a metal such as Al or Ag. For example, the pixel electrode 150 may have a three-layer structure including ITO/Ag/ITO.

A pixel-defining film 106 may be located on the second organic insulating layer 105 and may cover an edge of the pixel electrode 150. The pixel-defining film 106 may have an opening corresponding to the pixel PX, and at least a central portion of the pixel electrode 150 may be exposed through the opening. The pixel-defining film 106 may include an organic material such as polyimide or hexamethyldisiloxane (HMDSO). Also, a spacer may be located on the pixel-defining film 106.

An intermediate layer 160 and a counter electrode 170 may be located in the opening of the pixel-defining film 106. The intermediate layer 160 may include a low molecular weight material or a high molecular weight material. When the intermediate layer 160 includes a low molecular weight material, the intermediate layer 160 may include a hole injection layer, a hole transport layer, an emission layer, an electron transport layer, and/or an electron injection layer. When the intermediate layer 160 includes a high molecular weight material, the intermediate layer 160 may generally have a structure including a hole transport layer and an emission layer. A structure of the intermediate layer 160 is not limited thereto and may be any of various structures. For example, at least one of layers constituting the intermediate layer 160 may be integrally formed with the counter electrode 170. In another embodiment, the intermediate layer 160 may include a layer patterned to correspond to each of a plurality of pixel electrodes 150.

The counter electrode 170 may include a light-transmitting conductive layer formed of a light-transmitting conductive oxide such as ITO, In₂O₃, or IZO. The pixel electrode 150 may act as an anode of a light-emitting diode, and the counter electrode 170 may act as a cathode of the light emitting diode. Polarities of the electrodes may, however, be applied in reverse.

The counter electrode 170 may be located on the intermediate layer 160 and may extend onto the pixel-defining layer 106. That is, the counter electrode 170 may be integrally formed to cover a plurality of pixels. The counter electrode 170 may be electrically in contact with a common power supply line (not shown) located in the peripheral area PA. In an embodiment, the counter electrode 170 may extend to a blocking wall (not shown).

A thin-film encapsulation layer TFE may be located to entirely cover the first display panel 10 or the second display panel 20. The thin-film encapsulation layer TFE may extend to the outside of the common power supply line (not shown). The thin-film encapsulation layer TFE may include a first inorganic encapsulation layer 310, a second inorganic encapsulation layer 330, and an organic encapsulation layer 320 located between the first inorganic encapsulation layer 310 and the second inorganic encapsulation layer 330. Each of the first and second inorganic encapsulation layers 310 and 330 may include at least one inorganic material from among aluminum oxide, titanium oxide, tantalum oxide, hafnium oxide, zinc oxide, silicon oxide, silicon nitride, and silicon oxynitride.

Each of the first inorganic encapsulation layer 310 and the second inorganic encapsulation layer 330 may have a single or multi-layer structure including the above material. The first inorganic encapsulation layer 310 and the second inorganic encapsulation layer 330 may include the same material or different materials. Thicknesses of the first inorganic encapsulation layer 310 and the second inorganic encapsulation layer 330 may be different from each other. A thickness of the first inorganic encapsulation layer 310 may be greater than a thickness of the second inorganic encapsulation layer 330. Alternatively, a thickness of the second inorganic encapsulation layer 330 may be greater than a thickness of the first inorganic encapsulation layer 310, or thicknesses of the first inorganic encapsulation layer 310 and the second inorganic encapsulation layer 330 may be the same.

The organic encapsulation layer 320 may include a monomer-based material or a polymer-based material. Examples of the polymer-based material may include an acrylic resin, an epoxy resin, polyimide, and polyethylene. In an embodiment, the organic encapsulation layer 320 may include acrylate.

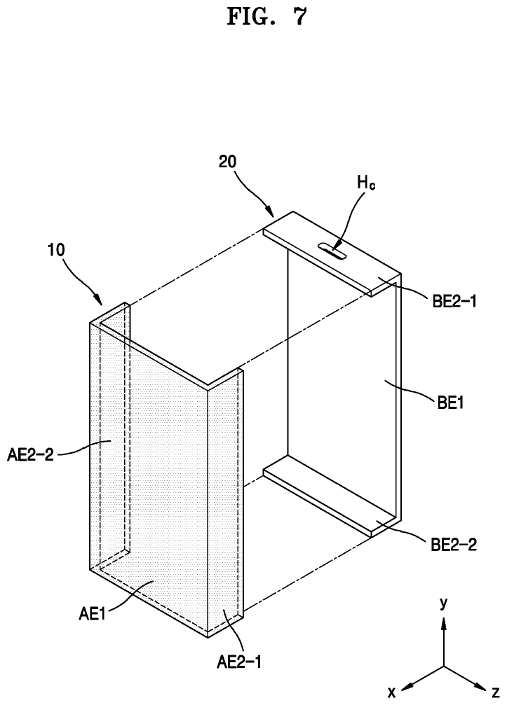

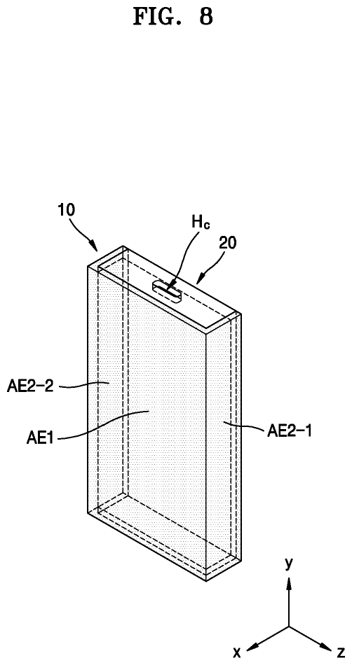

FIGS. 7 and 8 are perspective views illustrating a multi-sided light-emitting display apparatus, including the first display panel 10 of FIG. 1 and the second display panel 20 of FIG. 2, according to an embodiment. For reference, FIG. 7 is a view schematically illustrating a state before the multi-sided light-emitting display apparatus is assembled. FIG. 8 is a view illustrating a state after the multi-sided light-emitting display apparatus is assembled (hereinafter, referred to as an assembled state).

For reference, in the description of FIGS. 7 and 8, description that was already provided above with reference to FIGS. 1 to 6 may not be duplicated below.

As shown in FIGS. 7 and 8, the first display panel 10 and the second display panel 20 may be assembled. FIG. 7 shows the first display area AE1 of the first display panel 10 and the second display area BE1 of the second display panel 20 positioned for assembly. In this case, shapes of the first display area AE1 and the second display area BE1 may be the same or similar to each other. A rear surface of the first display area AE1 and a rear surface of the second display area BE1 may face each other, and thus, a display screen may face the outside of the multi-sided light-emitting display apparatus when assembled.

The 1-1 edge area AE2-1 and the 1-2 edge area AE2-2 may be in a bent state, and rear surfaces of the 1-1 edge area AE2-1 and the 1-2 edge area AE2-2 may face each other. Similarly, the 2-1 edge area BE2-1 and the 2-2 edge area BE2-2 may be in a bent state, and rear surfaces of the 2-1 edge area BE2-1 and the 2-2 edge area BE2-2 may also face each other. For assembly, a distance between the 1-1 edge area AE2-1 and the 1-2 edge area AE2-2 may be equal to a width of the 2-1 edge area BE2-1 and the 2-2 edge area BE2-2.

In detail, the multi-sided light-emitting display apparatus may include the first display panel 10. The first display panel 10 may include the first display area AE1 and may include the 1-1 edge area AE2-1 and the 1-2 edge area AE2-2 located on opposite sides of the first display area AE1.

In detail, the multi-sided light-emitting display apparatus may include the second display panel 20. The second display panel 20 may include the second display area BE1 facing away from the first display area AE1, and the 2-1 edge area BE2-1 and the 2-2 edge area BE2-2 located on opposite sides of the second display area BE1. In this case, the second display panel 20 may be assembled with the first display panel 10.

The first display panel 10 and the second display panel 20 may be assembled by adhering with an adhesive, fastening with a fastening structure (e.g., female/male fastening structure), or assembling with an assembly structure, and although a specific example of assembly is not described in detail, generally known assembly methods may be used.

In an embodiment, the 1-1 edge area AE2-1 and the 1-2 edge area AE2-2 in the embodiment of FIGS. 7 and 8 are bent toward the second display area BE1. That is, the 1-1 edge area AE2-1 and the 1-2 edge area AE2-2 are bent to extend toward the second display area BE1. The 2-1 edge area BE2-1 and the 2-2 edge area BE2-2 may be bent toward the first display area AE1. That is, in the bent state, the 2-1 edge area BE2-1 and the 2-2 edge area BE2-2 may extend toward the first display area AE1.

In an embodiment, the 1-1 edge area AE2-1 and the 1-2 edge area AE2-2 may face each other, and the 2-1 edge area BE2-1 and the 2-2 edge area BE2-2 may face each other. In detail, the rear surface of the 1-1 edge area AE2-1 and the rear surface of the 1-2 edge area AE2-2, where an image is not displayed, may face each other, and the rear surface of the 2-1 edge area BE2-1 and the rear surface of the 2-2 edge area BE2-2, where an image is not displayed, may face each other.

The above edge areas may constitute a side display area of the multi-sided light-emitting display apparatus according to an embodiment. Also, the first display area AE1 and the second display area BE1 may constitute front and rear display areas of the multi-sided light-emitting display apparatus according to an embodiment.

In an embodiment, a distance between the 1-1 edge area AE2-1 and the 1-2 edge area AE2-2 in the bent state may be equal to the short width W2 of the second display area BE1. As a result, the second display area BE1 fits between the 1-1 edge area AE2-1 and the 1-2 edge area AE2-2, and the first display panel 10 and the second display panel 20 may be assembled.

In an embodiment, a distance between the 1-1 edge area AE2-1 and the 1-2 edge area AE2-2 in the bent state may be equal to a long width of the 2-1 edge area BE2-1. A distance between the 1-1 edge area AE2-1 and the 1-2 edge area AE2-2 in the bent state may be equal to a long width of the 2-2 edge area BE2-2. The long width L1 of the 1-1 edge area AE2-1 may be equal to the long width L1 of the first display area AE1. A long width of the 2-1 edge area BE2-1 may be equal to the short width W2 of the second display area BE1.

In an embodiment, the first display area AE1, the 1-1 edge area AE2-1 and the 1-2 edge area AE2-2 may cover side surfaces or edges of the 2-1 edge area BE2-1. In an embodiment, the 1-1 edge area AE2-1 and the 1-2 edge area AE2-2 may cover both side surfaces or edges of the second display area BE1. In an embodiment, the first display area AE1, the 1-1 edge area AE2-1, and the 1-2 edge area AE2-2 may cover side surfaces or edges of the 2-2 edge area BE2-2. That is, the multi-sided light-emitting display apparatus may be assembled so that the first display panel 10 surrounds the second display panel 20.

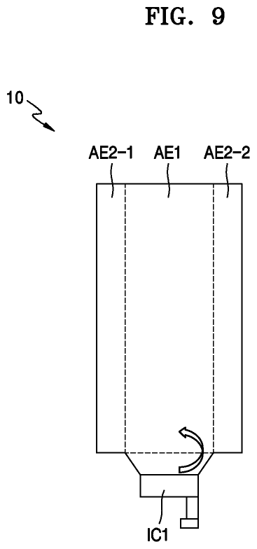

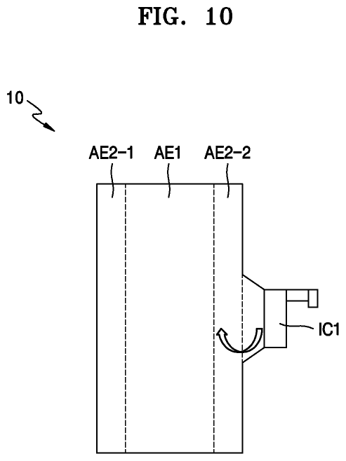

FIG. 9 schematically illustrates an unfolded state of the first display panel 10 of FIG. 1 and a first example a first driving circuit unit is attached to the first display panel 10 of FIG. 1. FIG. 10 schematically illustrates a second example where a first driving circuit is attached to the first display panel 10 of FIG. 1. For reference, in the description of FIGS. 9 and 10, description that was provided above with reference to FIGS. 1 to 8 may not be duplicated below.

The multi-sided light-emitting display apparatus according to an embodiment may further include a first driving circuit unit IC1 as shown in FIGS. 9 and 10. The first driving circuit unit IC1 may be electrically connected to the first display panel 10 and may generate or transmit an electrical signal for driving the first display panel 10.

In an assembled state, the first driving circuit unit IC1 may be located inside the multi-sided light-emitting display apparatus. That is, the first driving circuit unit IC1 may be located in an inner space defined by the first display panel 10 and the second display panel 20 in the assembled state. As a result, the first through-hole Hc may be needed to connect the first driving circuit unit IC1 to components outside of the multi-sided light-emitting display apparatus.

As shown in FIG. 9, the first driving circuit unit IC1 may be attached to the first display area AE1 or may be electrically connected to the first display area AE1. For example, the first driving circuit unit IC1 may include a driver IC connected to pads in a peripheral area that extend from one of the short sides of the first display area AE1. When a driver IC is attached, the first driving circuit unit IC1 may be attached to a rear surface of the peripheral area extending from the first display area AE1 and may transmit an electrical signal not only to pixels located in the first display area AE1 but also to pixels located in the 1-1 edge area AE2-1 and the 1-2 edge area AE2-2.

In an embodiment, the first driving circuit unit IC1 may be bent toward the second display area BE1 during assembly, like the 1-1 edge area AE2-1 and the 1-2 edge area AE2-2. Furthermore, the first driving circuit unit IC1 may be folded up to the rear surface of the first display area AE1. In other words, the first driving circuit unit IC1 may be bent by 90° or more and located inside the multi-sided light-emitting display apparatus in the assembled state but may be bent or folded so as not to cause interference or contact with other components as much as possible. To this end, a portion of the first driving circuit unit IC1 where the first driving circuit unit IC1 and the first display area AE1 are connected to each other may be flexible or formed of a flexible material.

For convenience of assembly, connecting the first driving circuit unit IC1 to one of short sides of the first display area AE1, as shown in FIG. 9, may be preferable.

As shown in FIG. 10, the first driving circuit unit IC1 may be attached to the 1-2 edge area AE2-2 or may be electrically connected to the 1-2 edge area AE2-2. However, this is merely an example. Alternatively, the first driving circuit unit IC1 may be attached to the 1-1 edge area AE2-1 or electrically connected to the 1-1 edge area AE2-1, instead of the 1-2 edge area AE2-2. In either case, the first driving circuit unit IC1 may transmit an electrical signal not only to pixels located in the first display area AE1 but also to pixels located in the 1-1 edge area AE2-1 and the 1-2 edge area AE2-2.

In an embodiment, the first driving circuit unit IC1 of FIG. 10 may be bent or folded in the same direction as a direction in which the 1-1 edge area AE2-1 is bent. As a result of bending, the first driving circuit unit IC1 may be located inside the multi-sided light-emitting display apparatus in the assembled sate, and interference or contact with other components inside the multi-sided light-emitting display apparatus may be minimized. To this end, a portion of the first driving circuit unit IC1 where the first driving circuit unit IC1 and the first display area AE1 are connected to each other may be flexible or formed of a flexible material.

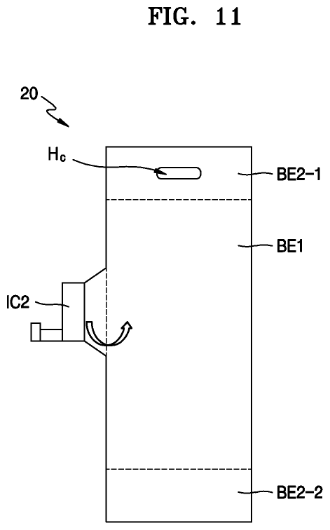

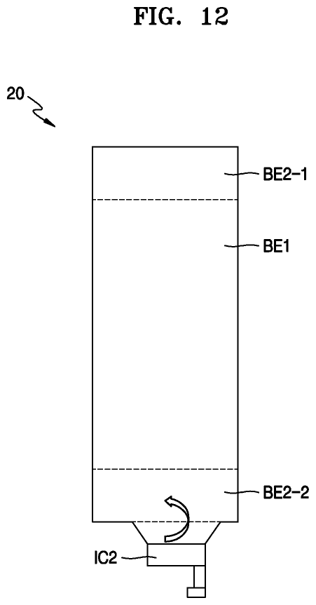

FIG. 11 schematically illustrates an unfolded state of the second display panel 20 of FIG. 2 and an example where a second driving circuit is attached to the second display panel 20 of FIG. 2. FIG. 12 schematically illustrates an alternative example where a second driving circuit is attached to the second display panel 20 of FIG. 2. For reference, in the description of FIGS. 11 and 12, description that was provided above with reference to FIGS. 1 to 10 may not be duplicated below.

The multi-sided light-emitting display apparatus according to an embodiment may further include a second driving circuit unit IC2 as shown in FIGS. 11 and 12. The second driving circuit unit IC2 may be electrically connected to the second display panel 20 and may generate or transmit an electrical signal for driving the second display panel 20.

In an assembled state, the second driving circuit unit IC2 may be located inside the multi-sided light-emitting display apparatus. That is, the second driving circuit unit IC2 may be located in an inner space defined by the first display panel 10 and the second display panel 20 in the assembled state. As a result, the first through-hole Hc may be needed to connect the second driving circuit unit IC2 to components outside of the multi-sided light-emitting display apparatus.

As shown in FIG. 11, the second driving circuit unit IC2 may be attached to and extend from the second display area BE1 or may be electrically connected to the second display area BE1. In particular, the second driving circuit unit IC2 may include a driver IC connected to pads in a peripheral area that extends from one of the long sides of the second display area BE1. When the second driving circuit unit IC2 includes an attached driver IC, the driver IC may be attached to a rear surface of the peripheral area extending the second display area BE1. In any case, the second driving circuit unit IC2 may transmit an electrical signal not only to pixels located in the second display area BE1 but also to pixels located in the 2-1 edge area BE2-1 and the 2-2 edge area BE2-2.

In an embodiment, the second driving circuit unit IC2 may be bent toward the first display area AE1 during assembly, like the 2-1 edge area BE2-1 and the 2-2 edge area BE2-2. Furthermore, the second driving circuit unit IC2 may be folded up to the rear surface of the second display area BE1. In other words, the second driving circuit unit IC2 may be bent by 90° or more and located inside the multi-sided light-emitting display apparatus in the assembled state but may be bent or folded so as not to cause interference or contact with other components as much as possible. To this end, a portion of the second driving circuit unit IC2 where the second driving circuit unit IC2 and the second display area BE1 are connected to each other may be flexible or formed of a flexible material.

Connecting the second driving circuit unit IC2 to one of long sides of the second display area BE1 as shown in FIG. 11 may be preferred for convenience of assembly.

As shown in FIG. 12, the second driving circuit unit IC2 may be attached to the 2-2 edge area BE2-2 or may be electrically connected to the 2-2 edge area BE2-2. However, this is merely an example for convenience of explanation, and in FIG. 12, the second driving circuit unit IC2 may be attached to the 2-1 edge area BE2-1 or electrically connected to the 2-1 edge area BE2-1, instead of the 2-2 edge area BE2-2. In any case, the second driving circuit unit IC2 may transmit an electrical signal not only to pixels located in the second display area BE1 but also to pixels located in the 2-1 edge area BE2-1 and the 2-2 edge area BE2-2.

Preferably, the second driving circuit unit IC2 may be attached or electrically connected to the 2-2 edge area BE2-2, rather than the 2-1 edge area BE2-1. This may be because the first through-hole Hc is formed in the 2-1 edge area BE2-1. This is because, as the distance between the first through-hole Hc and the second driving circuit unit IC2 decreases, the probability of affecting an electrical signal transmitted to a pixel far from the second driving circuit unit IC2 increases.

when the second display panel 20 employs the first through-hole Hc, wiring in the second display panel 20 should be routed to avoid the first through-hole Hc, and thus, lengths of wiring connected to some pixels may be different from lengths of wiring connected to other pixels. Accordingly, it is preferable that the second driving circuit unit IC2 is as far away from the first through-hole Hc as possible.

However, although the example in which the first through-hole Hc is located or formed in the 2-1 edge area BE2-1 is shown for convenience of explanation, the first through-hole Hc may be alternatively located or formed in the 2-2 edge area BE2-2. In this case, contrary to the above example, it may be preferable that the second driving circuit unit IC2 is attached to the 2-1 edge area BE2-1 or electrically connected to the 2-1 edge area BE2-1.

In an embodiment, the second driving circuit unit IC2 may be bent or folded in the same direction as a direction in which the 2-1 edge area BE2-1 and the 2-2 edge area BE2-2 are bent. As a result, the second driving circuit unit IC2 may be located inside the multi-sided light-emitting display apparatus in the assembled state, and interference or contact with other components inside the multi-sided light-emitting display apparatus may be minimized. To this end, a portion of the second driving circuit unit IC2 where the second driving circuit unit IC2 and the second display area BE1 are connected to each other may be flexible or formed of a flexible material.

In an embodiment, in the multi-sided light-emitting display apparatus in the assembled state of FIG. 8, when the first display panel 10 is configured as shown in FIG. 9, it may be preferable that the second display panel 20 is configured as shown in FIG. 11. This specific combination may minimize interference between the first driving circuit unit IC1 and the second driving circuit unit IC2 in the assembled state.

In an embodiment, in the multi-sided light-emitting display apparatus in the assembled state of FIG. 8, when the first display panel 10 is configured as shown in FIG. 10, it may be preferable that the second display panel 20 is configured as shown FIG. 12. This specific combination may minimize interference between the first driving circuit unit IC1 and the second driving circuit unit IC2 in the assembled state.

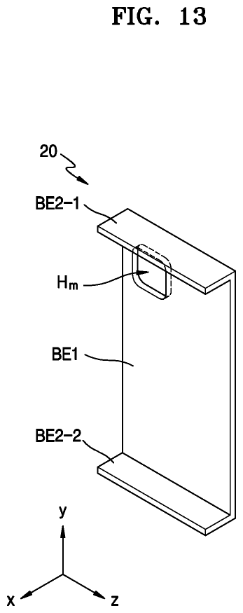

FIG. 13 is a perspective view schematically illustrating the second display panel 20 including a second through-hole Hₘ. For reference, in the description of FIG. 13, description provided above with reference to FIGS. 1 to 12 may not be duplicated below.

As shown in FIG. 13, the second display panel 20 may include the second through-hole Hₘ. The second through-hole Hₘ may be located or formed in the second display area BE1 for a component such as a camera device to be located inside the multi-sided light-emitting display apparatus in an assembled state. That is, the second display area BE1 may include the second through-hole Hₘ for a component.

In an embodiment, when a sensor or a camera module having a specific function is located or provided inside the multi-sided light-emitting display apparatus, information from outside of the multi-sided light-emitting display apparatus may be obtained or sensed through the second through-hole Hₘ.

For convenience of explanation, FIG. 13 shows the second through-hole Hₘ located or formed in the second display panel 20, but the second through-hole Hₘ may be alternatively located or formed in the first display panel when necessary. In addition, a third through-hole (not shown) may be further formed, and the second through-hole Hₘ and the third through-hole (not shown) may be located or formed in the same display panel or may be respectively located or formed in different display panels.

Also, for convenience of explanation, although FIG. 13 shows the second through-hole Hₘ located or formed in the second display area BE1 of the second display panel 20, the second through-hole Hₘ may be located or formed in the 2-1 edge area BE2-1 or the 2-2 edge area BE2-2.

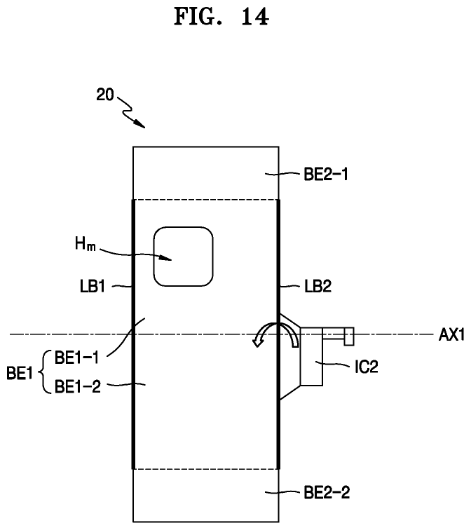

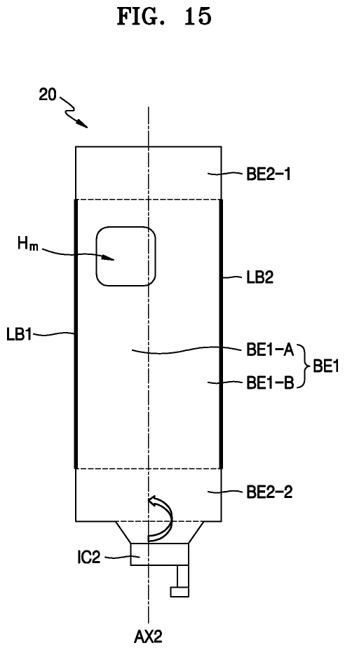

FIG. 14 is a view schematically illustrating a fifth example where a second driving circuit is attached to the second display panel 20 of FIG. 13. FIG. 15 schematically illustrates a sixth example where a second driving circuit is attached to the second display panel 20 of FIG. 13.

For reference, in the description of FIGS. 14 and 15, description provided above with reference to FIGS. 1 to 13 may not be duplicated below.

As shown in FIG. 14, the second through-hole Hₘ may be located or formed in the second display area BE1. That is, the second display area BE1 may include the second through-hole Hₘ. This may be to ensure a sufficient distance between the second through-hole Hₘ and the first through-hole Hc located or formed in the 2-2 edge area BE2-2, as in other examples.

The second through-hole Hₘ may be located or formed to be biased to one side with respect to a first virtual central line AX1 passing through center points of long sides of the second display area BE1. In FIG. 14, the second through-hole Hₘ is located closer to the 2-1 edge area BE2-1 and farther from the 2-2 edge area BE2-2.

In an embodiment, the second through-hole Hₘ may be closer to the 2-1 edge area BE2-1 with respect to the first virtual central line AX1. For example, the second display area BE1 may be divided into a 2-1 display area (the second display area BE1 close to the 2-1 edge area BE2-1) and a 2-2 display area (the second display area BE1 close to the 2-2 edge area BE2-2) with respect to the first virtual central line AX1, and the second through-hole Hₘ may overlap more with the 2-1 display area than with the 2-2 display area.

As shown in FIG. 14, the second driving circuit unit IC2 may be attached or electrically connected to the second display area BE1. The second driving circuit unit IC2 may be attached or electrically connected to one of long sides of the second display area BE1. In this case, the second driving circuit unit IC2 may be located opposite to the second through-hole Hₘ. The second driving circuit unit IC2 may also be located or formed to be biased to one side with respect to the first virtual central line AX1 passing through center points of the long sides of the second display area BE1, and the second driving circuit unit IC2 is located closer to the 2-2 edge area BE2-2 and farther from the 2-1 edge area BE2-1.

In an embodiment, the second driving circuit unit IC2 may be located closer to the 2-2 edge area BE2-2 with respect to the first virtual central line AX1. For example, the second display area BE1 may be divided into the 2-1 display area BE1-1 (the second display area BE1 close to the 2-1 edge area BE2-1) and the 2-2 display area BE1-2 (the second display area BE1 close to the 2-2 edge area BE2-2) with respect to the first virtual central line AX1, and in the bent state, the second driving circuit unit IC2 may overlap more with the 2-2 display area BE1-2 than with the 2-1 display area BE1-1. This configuration may improve the stability of electrical signal distribution of the second driving circuit unit IC2 and keep the second driving circuit unit IC2 as far away as possible from the influence of change in wiring routing caused by the second through-hole Hₘ.

However, FIG. 14 shows only one example for convenience of illustration and explanation, and the second through-hole Hₘ may be alternatively located closer to the 2-2 edge area BE2-2 unlike in FIG. 14. In this case, the second driving circuit unit IC2 may be located closer to the 2-1 edge area BE2-1.

FIG. 15 another example in which the second through-hole Hₘ is located or formed in the second display area BE1. That is, the second display area BE1 may include the second through-hole Hₘ.

The second through-hole Hₘ may be located or formed to be biased to one side with respect to a second virtual central line AX2 passing through center points of short sides of the second display area BE1. In FIG. 15, the second through-hole Hₘ may be located closer to the 2-1 edge area BE2-1 and farther from the 2-2 edge area BE2-2. Also, the second through-hole Hₘ may be located closer to a first long side LB1 and farther from a second long side LB2.

For example, the second through-hole Hₘ may be located closer to the first long side with respect to the second virtual central line AX2. For example, the second display area BE1 may be divided into a 2-A display area BE1-A (the second display area BE1 close to the first long side) and a 2-B display area BE1-B (the second display area BE1 close to the second long side) with respect to the second virtual central line AX2, and in the bent state of the second display panel 20, the second through-hole Hₘ may overlap more with the 2-A display area BE1-A than with the 2-B display area BE1-B.

As shown in FIG. 15, the second driving circuit unit IC2 may be attached or electrically connected to the 2-2 edge area BE2-2. In this case, the second driving circuit unit IC2 may be located opposite to the second through-hole Hₘ. The second driving circuit unit IC2 may also be located or formed to be biased to one side with respect to the second virtual central line AX2, and the second driving circuit unit IC2 is located closer to the second long side LB2 and farther from the first long side LB1.

For example, the second driving circuit unit IC2 may be located closer to the 2-B display area BE1-B with respect to the second virtual central line AX2. For example, in a bent state, the second driving circuit unit IC2 may overlap more the 2-B display area BE1-B than with the 2-A display area BE1-A. This is to improve the stability of electrical signal distribution of the second driving circuit unit IC2, and to keep the second driving circuit unit IC2 as far away as possible from the influence of changes in routing of wiring caused by the second through-hole Hₘ.

However, FIG. 15 shows only an example for convenience of illustration and explanation, and the second through-hole Hₘ may be alternatively located closer to the second long side LB2 unlike in FIG. 15. In this case, the second driving circuit unit IC2 may be located closer to the first long side LB1.

In an embodiment, in the multi-sided light-emitting display apparatus in the assembled state of FIG. 8, when the first display panel 10 has the configuration shown in FIG. 9, it may be preferable that the second display panel 20 has the configuration shown in FIG. 14. This specific combination may minimize interference between the first driving circuit unit IC1 and the second driving circuit unit IC2 in the assembled state.

In an embodiment, in the multi-sided light-emitting display apparatus in the assembled state of FIG. 8, when the first display panel 10 has the configuration shown in FIG. 10, it may preferable that the second display panel 20 has the configuration shown in FIG. 15. This specific combination may minimize interference between the first driving circuit unit IC1 and the second driving circuit unit IC2 in the assembled state.

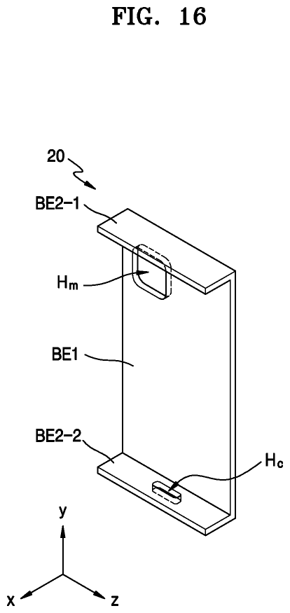

FIG. 16 is a schematic perspective view illustrating the second display panel 20 including the first through-hole Hc and the second through-hole Hₘ. For reference, in the description of FIG. 16, description already provided above with respect to FIGS. 1 to 15 may not be duplicated below.

As shown in FIG. 16, the second display panel 20 may include both the first through-hole Hc and the second through-hole Hₘ. For example, the first through-hole Hc may be located or formed in the 2-2 edge area BE2-2, and the second through-hole Hₘ may be located or formed in the second display area BE1. Positioning of the first through-hole Hc and the second through-hole Hₘ may be as described above.

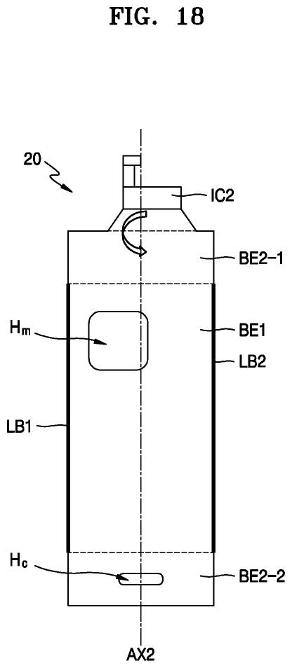

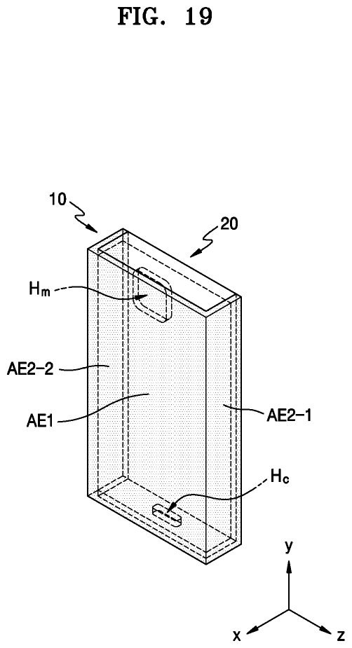

FIG. F 17 schematically illustrates a seventh example where a second driving circuit is attached to the second display panel 20 of FIG. 16. FIG. 18 schematically illustrates an eighth example where a second driving circuit is attached to the second display panel 20 of FIG. 16. FIG. 19 is a perspective view schematically illustrating an embodiment of the multi-sided light-emitting display apparatus in which the first display panel 10 of FIG. 1 and the display panel of FIG. 16 are assembled.

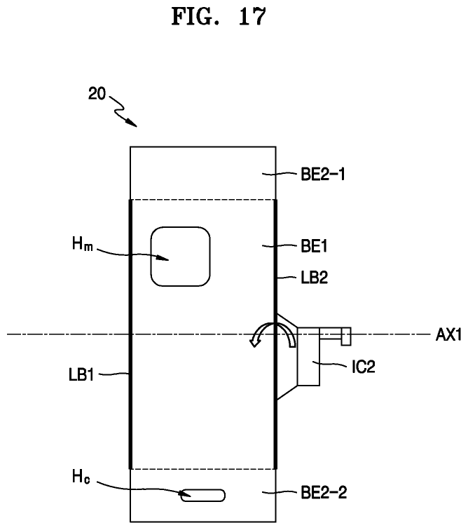

For reference, in the description of FIGS. 17 to 19, description that was already provided above with reference to FIGS. 1 to 16 may not be duplicated below.

As shown in FIG. 17, the second through-hole Hₘ may be located or formed in the second display area BE1, as described with reference to FIGS. 14 and 15. In addition, the first through-hole Hc may be located or formed in the 2-2 edge area BE2-2 in order to be farther away from the second through-hole Hₘ.

The second driving circuit unit IC2 may be attached or electrically connected to the second display area BE1. The second driving circuit unit IC2 may be attached or electrically connected to one of long sides of the second display area BE1. In this case, the second driving circuit unit IC2 may be located opposite to the second through-hole Hₘ. The second driving circuit unit IC2 may also be located to be biased to one side with respect to the first virtual central line AX1 passing through center points of the long sides of the second display area BE1, and the second driving circuit unit IC2 is located closer to the 2-2 edge area BE2-2 and farther from the 2-1 edge area BE2-1. In this case, the arrangement of the second driving circuit unit IC2 has been described with reference to FIG. 14, and thus, will not be repeatedly described. However, the second driving circuit unit IC2 may be spaced apart from the first through-hole Hc and the second through-hole Hₘ by the same or similar distance. That is, the second driving circuit unit IC2 may be located to be minimally affected by the first through-hole Hc and the second through-hole Hₘ.

As shown in FIG. 18, the second through-hole Hₘ may be located or formed in the second display area BE1. That is, the second display area BE1 may include the second through-hole Hₘ. The second through-hole Hₘ may be located or formed to be biased to one side with respect to the second virtual central line AX2 passing through center points of short sides of the second display area BE1. In FIG. 18, the second through-hole Hₘ may be located closer to the 2-1 edge area BE2-1 and farther from the 2-2 edge area BE2-2. Also, the second through-hole Hₘ may be located closer to the first long side and farther from the second long side. Positioning of the second through-hole Hₘ has been described with reference to FIGS. 14 and 15, and thus, will not be repeatedly described.

The first through-hole Hc may be located in the 2-2 edge area BE2-2, in order to be farther away from the second through-hole Hₘ. The first through-hole Hc has been described with reference to FIG. 17, and thus, will not be repeatedly described.

A second driving circuit may be attached or electrically connected to the 2-1 edge area BE2-1. The second driving circuit may not be attached or electrically connected to the 2-2 edge area BE2-2 in which the first through-hole Hc is located. This is because, if the second driving circuit is attached or electrically connected to the 2-2 edge area BE2-2, a distance between the second driving circuit and the first through-hole Hc would be very close. When the second driving circuit is attached or electrically connected to the 2-1 edge area BE2-1, a distance between the second driving circuit and the first through-hole Hc may be relatively far. Accordingly, in order to minimize the influence of wiring that is changed around the first through-hole Hc, the second driving circuit unit IC2 may be attached or electrically connected to the 2-1 edge area BE2-1 in which the first through-hole Hc is not located.

As shown in FIG. 19, the multi-sided light-emitting display apparatus in the assembled state may include the first display panel 10 of FIG. 1 and the second display panel 20 of FIG. 16.

In an embodiment, in the multi-sided light-emitting display apparatus in the assembled state of FIG. 19, when the first display panel 10 has the configuration shown in FIG. 9, it may be preferable that the second display panel 20 has the configuration of FIG. 17. This specific combination may minimize interference between the first driving circuit unit IC1 and the second driving circuit unit IC2 in the assembled state.

In an embodiment, in the multi-sided light-emitting display apparatus in the assembled state of FIG. 19, when the first display panel 10 has the configuration shown in FIG. 10, it may be preferable that the second display panel 20 have the configuration shown in FIG. 18. This specific combination may minimize interference between the first driving circuit unit IC1 and the second driving circuit unit IC2 in the assembled state.

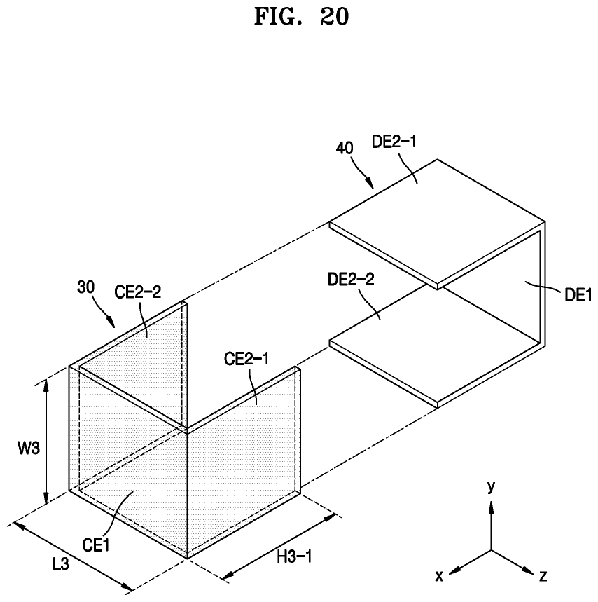

FIG. 20 is a perspective view schematically illustrating a multi-sided light-emitting display apparatus, according to another embodiment.

For reference, in the description of FIG. 20, description already provided above with reference to FIGS. 1 to 19 may not be duplicated below.

As shown in FIG. 20, a third display panel 30 may correspond to the first display panel 10, and a third display area CE1 of the third display panel 30 may have a square shape or a substantially square shape. Also, each of a 3-1 edge area CE2-1 and a 3-2 edge area CE2-2 of the third display panel 30 may also have a square shape or a substantially square shape, like the third display area CE1. For example, sizes of a horizontal width W3 and a vertical width L3 of the third display area CE1 may be the same or similar to each other, and the horizontal width W3 and the vertical width L3 of the third display area CE1 may be the same as or similar to a height width H3-1 of the 3-1 edge area CE2-1 and the 3-2 edge area CE2-2.

A fourth display panel 40 may correspond to the second display panel 20, and a fourth display area DE1 of the fourth display panel 40 may have a square shape or a substantially square shape. Also, each of a 4-1 edge area DE2-1 and a 4-2 edge area DE2-2 of the fourth display panel 40 may have a square shape or a substantially square shape, like the fourth display area DE1.

When the third display panel 30 and the fourth display panel 40 are assembled, a multi-sided light-emitting display apparatus having a cubic or regular hexahedral shape or a substantially cubic or regular hexahedral shape may be provided.

Various types of multi-sided light-emitting display apparatuses may be assembled by adjusting specifications of display panels.

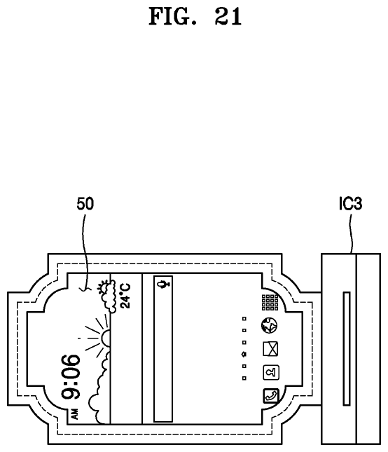

FIG. 21 is a view schematically illustrating a display apparatus, according to a comparative example.

As shown in FIG. 21, a display apparatus according to a comparative example may include a driving circuit IC and an edge display panel 50 using a side surface of the panel to provide a three-dimensional effect. As in the comparative example, to have a multi-sided light-emitting display panel having three or more surfaces, a special display panel shape is required, and thus various processes should be newly applied.

However, because the multi-sided light-emitting display apparatus of the disclosure as shown in FIGS. 1 to 20 may include the first display panel 10 and the second display panel 20 (or the third display panel 30 and the fourth display panel 40), there is no need to apply a new display panel design or process. Only a structure for attaching or connecting two display panels needs to be added.

Accordingly, the multi-sided light-emitting display apparatus of the disclosure as shown in FIGS. 1 to 20 has a new and remarkable effect in that the cost of new processes and panel designs may be significantly reduced, and various types of multi-sided light-emitting display apparatuses may be produced.

According to an embodiment, as described above, there may be provided a multi-sided light-emitting display apparatus that may be simply assembled using only a first display panel and a second display panel. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A multi-sided light-emitting display apparatus comprising:
a first display panel comprising a first display area, and a 1-1 edge area and a 1-2 edge area located on opposite sides of the first display area; and
a second display panel comprising a second display area parallel to the first display area, and a 2-1 edge area and a 2-2 edge area located on opposite sides of the second display area, the second display panel being assembled with the first display panel,
wherein the 1-1 edge area and the 1-2 edge area are bent toward the second display area, and the 2-1 edge area and the 2-2 edge area are bent toward the first display area.

2. The multi-sided light-emitting display apparatus of claim 1, wherein the 1-1 edge area and the 1-2 edge area are parallel to each other, and the 2-1 edge area and the 2-2 edge area are parallel to each other.

3. The multi-sided light-emitting display apparatus of claim 1, wherein the edge areas constitute a side display area of the multi-sided light-emitting display apparatus, and the first display area and the second display area constitute a front display area and a rear display area of the multi-sided light-emitting display apparatus.

4. The multi-sided light-emitting display apparatus of claim 1, wherein a distance between the 1-1 edge area and the 1-2 edge area in a bent state is equal to a short width of the second display area.

5. The multi-sided light-emitting display apparatus of claim 4, wherein the distance between the 1-1 edge area and the 1-2 edge area in the bent state is equal to a long width of the 2-1 edge area.

6. The multi-sided light-emitting display apparatus of claim 4, wherein the distance between the 1-1 edge area and the 1-2 edge area in the bent state is equal to a long width of the 2-2 edge area.

7. The multi-sided light-emitting display apparatus of claim 1, wherein a long width of the 1-1 edge area is equal to a long width of the first display area.

8. The multi-sided light-emitting display apparatus of claim 7, wherein a long width of the 2-1 edge area is equal to a short width of the second display area.

9. The multi-sided light-emitting display apparatus of claim 1, wherein the first display area, the 1-1 edge area, and the 1-2 edge area in a bent state cover side surfaces of the 2-1 edge area.

10. The multi-sided light-emitting display apparatus of claim 9, wherein the 1-1 edge area and the 1-2 edge area in the bent state cover both side surfaces of the second display area.

11. The multi-sided light-emitting display apparatus of claim 10, wherein the first display area, the 1-1 edge area, and the 1-2 edge area in the bent state cover side surfaces of the 2-2 edge area.

12. The multi-sided light-emitting display apparatus of claim 1, further comprising:
a first driving circuit unit for driving the first display panel; and
a second driving circuit unit for driving the second display panel.

13. The multi-sided light-emitting display apparatus of claim 12, wherein at least one of the first driving circuit unit and the second driving circuit unit is located in an inner space of the first display panel and the second display panel in an assembled state.

14. The multi-sided light-emitting display apparatus of claim 12, wherein the 2-1 edge area comprises a first through-hole for connecting an inner space and an outer space of the first display panel and the second display in the assembled state.

15. The multi-sided light-emitting display apparatus of claim 14, wherein the second driving unit is connected to an end of the 2-2 edge area.

16. The multi-sided light-emitting display apparatus of claim 12, wherein the second display area comprises a second through-hole for connecting the inner space and the outer space of the first display panel and the second display panel in the assembled state.

17. The multi-sided light-emitting display apparatus of claim 16, further comprising a camera device in the inner space adjacent to the second through-hole.

18. The multi-sided light-emitting display apparatus of claim 16, wherein the second driving unit is connected to one side surface of the second display area.

19. The multi-sided light-emitting display apparatus of claim 18, wherein the second through-hole is located closer to the 2-1 edge area than the 2-2 edge area.

20. The multi-sided light-emitting display apparatus of claim 19, wherein the second driving unit is located closer to the 2-2 edge area than the 2-1 edge area.
